(19) United States
(12) Patent Application Publication
(10) Pub. No.: US 2026/0169033 A1
(43) Pub. Date: Jun. 18, 2026

(54) VARIABLE ATTENUATOR, STEP ATTENUATOR, AND TEST APPARATUS

(71) Applicant: ADVANTEST CORPORATION, Tokyo (JP)

(72) Inventors: Takahiro TSUSHIMA, Miyagi (JP); Takaya ABE, Miyagi (JP)

(21) Appl. No.: 19/533,313

(22) Filed: Feb. 9, 2026

Related U.S. Application Data
(63) Continuation of application No. PCT/JP2023/030182, filed on Aug. 22, 2023.

(51) Int. Cl. G01R 1/30; G01R 1/20; G01R 1/24

(52) U.S. Cl. CPC G01R 1/30; G01R 1/203; G01R 1/24

(57) ABSTRACT

There is provided a variable attenuator including: a transmission line which has an open stub that is connected between an input and an output of the variable attenuator; a first switch which is connected between the input and a reference potential; and a second switch which is connected between the output and the reference potential.

The contents of the following patent application(s) are incorporated herein by reference:
NO. PCT/JP2023/030182 filed in WO on Aug. 22, 2023.

### BACKGROUND

### 1. Technical Field

The present invention relates to a variable attenuator, a step attenuator, and a test apparatus.

### 2. Related Art

Patent Document 1 discloses that “in the microwave circuit 1A, a line width step portion 32A is formed to protrude on one side of a transmission line 25A, that is, in the width direction (Y direction), in a central portion of the transmission line 25A in a longitudinal direction (X direction)” (paragraph 44). Patent Document 2 discloses that “the high-frequency device further includes terminals P1 and P2 for input/output of a high-frequency signal formed at the pattern conductor 1 and includes a ground terminal GND formed at the pattern conductor 5. The pattern conductors 1, 4, and 5 and the via conductors 2 and 3 connect the terminals P1 and P2 and the ground terminal GND to one another, thereby forming a signal line for transmitting a high-frequency signal” . . . “the high-frequency device functions as an attenuator as a result of a portion of the signal line having the resistances R1 and R2 to the high-frequency signal” (paragraphs 27 and 30). Patent Document 3 discloses that “many semiconductor RF switches today stack a multiplicity of low BVds transistors in series to improve the breakdown performance of the overall switch” (paragraph 6).

### RELATED ART DOCUMENTS

### Patent Document

Patent Document 1: Japanese Patent Application Publication No. 2014-241482
Patent Document 2: International Publication No. WO 2014/030469
Patent Document 3: Japanese Translation of PCT International Publication No. 2010-527179

### BRIEF DESCRIPTION OF THE DRAWINGS

FIG. 1 shows a configuration of a variable attenuator 10 according to the present embodiment.

FIG. 2 shows a configuration of a Modification Example of the variable attenuator 10 according to the present embodiment.

FIG. 3 shows a configuration of a step attenuator according to the present embodiment.

FIG. 4 shows a configuration of a test apparatus 400 according to the present embodiment.

FIG. 5 is an illustration for describing an output result of a Smith chart at each position of the variable attenuator 10 of the present embodiment.

FIG. 6 shows an output result of the Smith chart of the variable attenuator 10.

FIG. 7 shows an output result of the Smith chart of the variable attenuator 10.

FIG. 8 shows an output result of the Smith chart of the variable attenuator 10.

FIG. 9 shows an output result of the Smith chart of the variable attenuator 10.

FIG. 10 shows an output result of the Smith chart of the variable attenuator 10.

FIG. 11 is an illustration for describing each position of a variable attenuator 500 in a Reference Example.

FIG. 12 shows an output result of the Smith chart of the variable attenuator 500.

FIG. 13 shows an output result of the Smith chart of the variable attenuator 500.

FIG. 14 shows an output result of the Smith chart of the variable attenuator 500.

FIG. 15 shows a relationship between impedance of an open stub as seen from a connection position of a transmission line and a length.

FIG. 16 shows a simulation result of a state error of the variable attenuator having an attenuation amount of 8 dB.

FIG. 17 shows simulation results of insertion losses of the step attenuator in Example 2, Reference Example 2, and Reference Example 3.

FIG. 18 shows simulation results of state errors of the step attenuator in Example 2, Reference Example 2, and Reference Example 3.

### DESCRIPTION OF EXEMPLARY EMBODIMENTS

The present invention will be described below through embodiments of the invention, but the following embodiments do not limit the invention according to the claims. Further, not all of combinations of features described in the embodiments are essential to the solving means of the invention.

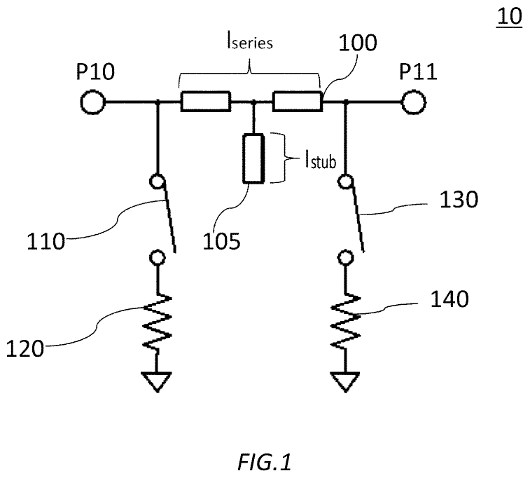

FIG. 1 shows a configuration of a variable attenuator 10 according to the present embodiment. The variable attenuator 10 includes an input terminal P10 and an output terminal P11. The variable attenuator 10 attenuates, for example, a high-frequency signal that is input to the input terminal P10, and outputs the attenuated signal from the output terminal P11. The variable attenuator 10 is capable of changing an attenuation amount of a signal by varying an internal resistance value.

The variable attenuator 10 includes a transmission line 100, a first switch 110, a first resistor 120, a second switch 130, and a second resistor 140. The transmission line 100 is connected between the input terminal P10 and the output terminal P11. The transmission line 100 outputs, from the output terminal P11, a signal that is input to the input terminal P10. The transmission line 100 can attenuate a high-frequency signal such as an RF signal in transmission. The transmission line 100 has a straight line connecting the input terminal P10 to the output terminal P11. A length (electrical length) Iₛₑᵣᵢₑₛ of the straight line may be in a range of λ/8<Iₛₑᵣᵢₑₛ<λ/4 with respect to a wavelength A of the signal that is transmitted.

The transmission line 100 has an open stub 105 which is connected between the input terminal P10 and the output terminal P11 of the variable attenuator 10. The open stub 105 branches from the straight line of the transmission line 100 between the input terminal P10 and the output terminal P11, and has an end portion that is open. The open stub 105 may be connected at any position of the straight line between the input terminal P10 and the output terminal P11 of the transmission line 100, and, for example, may be connected at a center position in the transmission line 100 between the input terminal P10 and the output terminal P11 of the variable attenuator 10. The open stub 105 is provided for an impedance conversion of the variable attenuator 10. The open stub 105 may have a length (electrical length) I_{stub} that is less than the length Iₛₑᵣᵢₑₛ of the straight line of the transmission line 100 between the input terminal P10 and the output terminal P11 of the variable attenuator 10. For example, the open stub 105 may have the length I_{stub} from a connection position (branch position) with respect to the wavelength A of the signal that is transmitted, in a range of λ/4>I_{stub} (in particular, λ/8≥I_{stub}) where the impedance of the open stub 105 as seen from the connection position indicates capacitance, and in a range of Iₛₑᵣᵢₑₛ>I_{stub}.

The first switch 110 is connected between the input terminal P10 and a reference potential. The first switch 110 switches between connecting and not connecting the input terminal P10 to the reference potential. The first switch 110 may be a shunt switch such as a HEMT (High Electron Mobility Transistor). The first resistor 120 is connected in series with the first switch 110 between the input terminal P10 and the reference potential. The first resistor 120 may be connected to an end portion of the first switch 110 on a reference potential side. Here, the reference potential may be a fixed potential such as the ground potential (0 V), and the same applies below.

The second switch 130 is connected between the output terminal P11 and the reference potential. The second switch 130 switches between connecting and not connecting the output terminal P11 to the reference potential. The second switch 130 may be a shunt switch such as the HEMT. The second resistor 140 is connected in series with the second switch 130 between the output terminal P11 and the reference potential. The second resistor 140 may be connected to an end portion of the second switch 130 on the reference potential side.

The first switch 110 and the second switch 130 are connected to a control circuit or the like which controls switching. The variable attenuator 10 can increase the attenuation amount by the control circuit turning on at least one of the first switch 110 or the second switch 130.

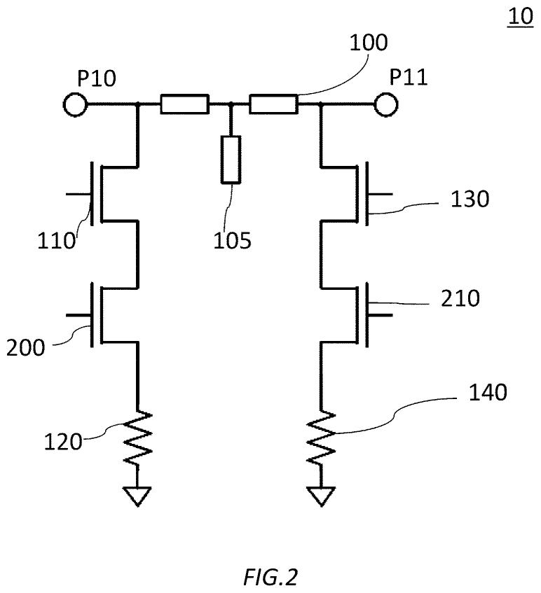

FIG. 2 shows a configuration of a Modification Example of the variable attenuator 10 according to the present embodiment. The variable attenuator 10 shown in FIG. 2 has a configuration and a function similar to those of the variable attenuator 10 in FIG. 1, but further includes a third switch 200 and a fourth switch 210. The third switch 200 is connected to the end portion of the first switch 110 on the reference potential side. The third switch 200 may be turned on at the same timing as the first switch 110 is turned on. The fourth switch 210 is connected to the end portion of the second switch 130 on the reference potential side. The fourth switch 210 may be turned on at the same timing as the second switch 130 is turned on. In FIG. 2, each of the first switch 110, the second switch 130, the third switch 200, and the fourth switch 210 may be the HEMT. The variable attenuator 10 in the Modification Example has shunt switches stacked in multiple stages, thereby making it possible to further reduce off-capacitance and making it possible to further enhance a withstand voltage.

It should be noted that the variable attenuator 10 is not limited to the configuration in which the two switches are connected as shown in FIG. 2, and may also have a configuration in which three or more switches are connected.

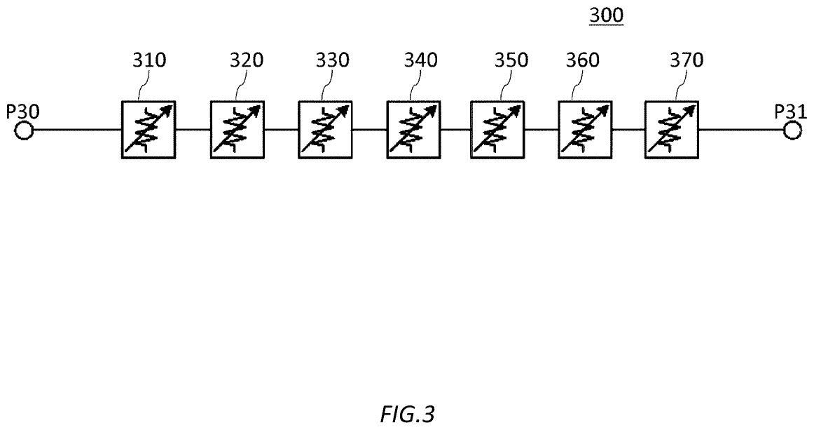

FIG. 3 shows a configuration of a step attenuator according to the present embodiment. A step attenuator 300 includes a plurality of variable attenuators 310 to 370 which are connected in cascade. In the embodiment of FIG. 3, the step attenuator 300 includes seven variable attenuators 310 to 370. Each of the variable attenuators 310 to 370 may have the same configuration as that of the variable attenuator 10 of the present embodiment shown in FIG. 1 or FIG. 2.

In the variable attenuator 310 of the first stage, the input terminal P10 is connected to an input terminal P30 of the step attenuator 300, and the output terminal P11 is connected to the input terminal P10 of the variable attenuator 320 of the second stage. One of the input terminal P10 and the output terminal P11 in each of the variable attenuators 320 to 360 of the second to sixth stages is connected to the other of the input terminal P10 and the output terminal P11 in each of the adjacent variable attenuators 320 to 360. The output terminal P11 of the variable attenuator 370 of the seventh stage is connected to an output terminal P31 of the step attenuator 300.

The step attenuator 300 may include the plurality of variable attenuators 310 to 370, all of which have the same configuration, or may include one or more variable attenuators 310 to 370 which have attenuation amounts different from each other.

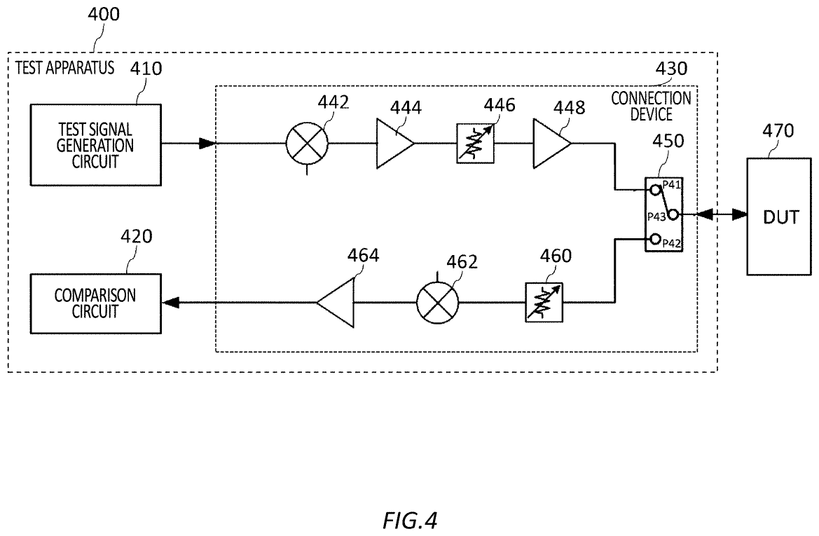

FIG. 4 shows a configuration of a test apparatus 400 according to the present embodiment. The test apparatus 400 may be Automated Test Equipment (ATE) that performs a test on a DUT (Device Under Test) 470. The test apparatus 400 may determine that the DUT 470 is a non-defective product, when a response signal which is output by the DUT 470, with respect to a test signal which is supplied to the DUT 470 during the test, matches an expected value for the response signal. The test apparatus 400 may determine that the DUT 470 is a defective product, when the response signal which is output by the DUT 470, with respect to any test signal which is supplied to the DUT 470 during the test, does not match a corresponding expected value.

The test apparatus 400 includes a test signal generation circuit 410, a comparison circuit 420, and a connection device 430. The test signal generation circuit 410 generates the test signal for testing the DUT 470. The comparison circuit 420 compares, with the expected value, the response signal which is output by the DUT 470 in response to the test signal.

The connection device 430 is connected to the test signal generation circuit 410 and the comparison circuit 420. The connection device 430 functions as a switch device that switches, for example, an input/output path of a signal such as an analog high-frequency signal (RF signal). The connection device 430 may be, as an example, an RF test front end that switches between a transmission system circuit which outputs a transmission signal and a reception system circuit to which a reception signal is input. The connection device 430 supplies the test signal from the test signal generation circuit 410 to the DUT 470, and supplies, to the comparison circuit 420, the response signal which is output by the DUT 470.

The connection device 430 has a first mixer 442, a gain amplifier 444, a first variable attenuator 446, a first power amplifier 448, a connection unit 450, a second variable attenuator 460, a second mixer 462, and a second power amplifier 464.

The first mixer 442 is connected to the test signal generation circuit 410. The first mixer 442 converts a frequency of the test signal from an intermediate frequency (IF) to a radio frequency (RF) by mixing the test signal generated by the test signal generation circuit 410 with a carrier wave. The gain amplifier 444 is connected between the test signal generation circuit 410 and the first variable attenuator 446, and is connected to the first mixer 442. The gain amplifier 444 amplifies and transmits the test signal frequency-converted by the first mixer 442. The first variable attenuator 446 is connected to the gain amplifier 444, and attenuates and transmits the test signal amplified by the gain amplifier 444. The first variable attenuator 446 may have the same configuration as that of the variable attenuator 10 shown in FIG. 1 or FIG. 2, or may have the same configuration as that of the step attenuator 300 shown in FIG. 3. The first power amplifier 448 is connected to the first variable attenuator 446, and amplifies and transmits the test signal attenuated by the first variable attenuator 446.

The connection unit 450 is connected to the first power amplifier 448. The connection unit 450 is a switch that switches between connecting and not connecting a terminal P41 or a terminal P42 to a terminal P43. The terminal P41 is connected to the test signal generation circuit 410, the terminal P42 is connected to the comparison circuit 420, and the terminal P43 is connected to the DUT 470.

The second variable attenuator 460 is connected to the terminal P42, and attenuates and transmits the response signal received from the DUT 470. The second variable attenuator 460 may have the same configuration as that of the variable attenuator 10 shown in FIG. 1 or FIG. 2, or may have the same configuration as that of the step attenuator 300 shown in FIG. 3. The second mixer 462 is connected between the comparison circuit 420 and the second variable attenuator 460. The second mixer 462 converts the frequency of the response signal from the RF to the IF by mixing the response signal received from the DUT 470 with the carrier wave. The second power amplifier 464 is connected between the second mixer 462 and the comparison circuit 420, and amplifies and transmits the response signal frequency-converted by the second mixer 462.

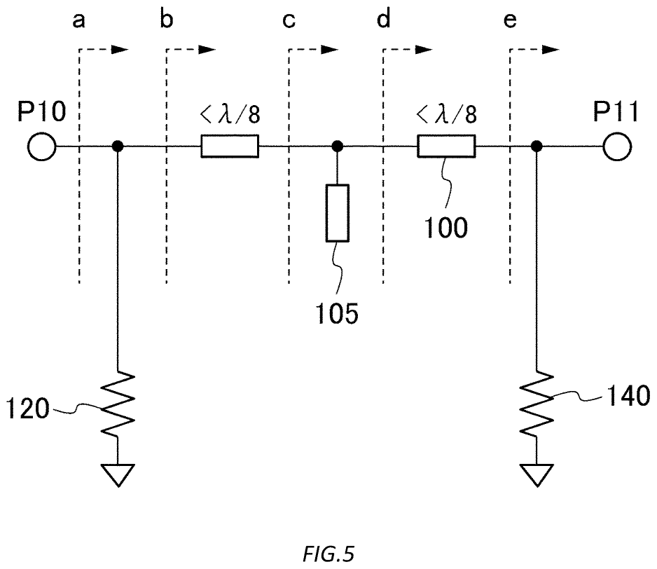

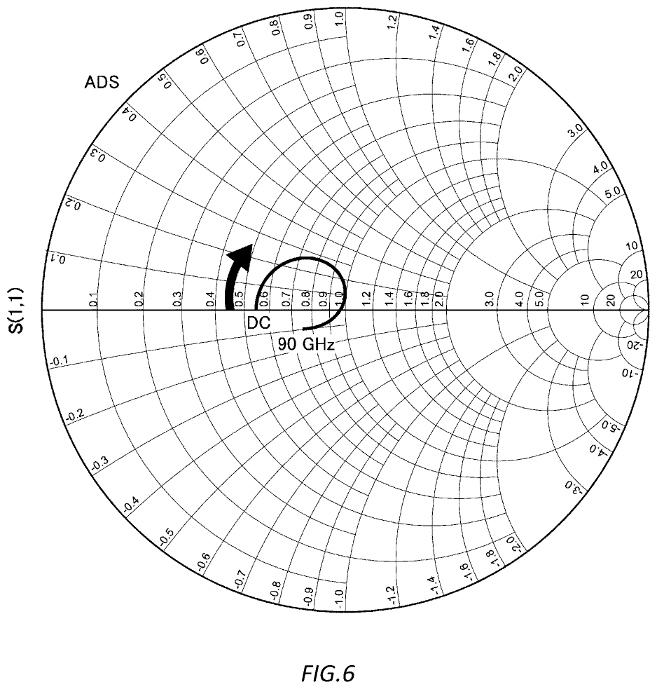

FIG. 5 is an illustration for describing an output result of a Smith chart at each position of the variable attenuator 10 of the present embodiment. FIG. 5 shows a state in which the first switch 110 and the second switch 130 are turned on, in the variable attenuator 10 of the present embodiment shown in FIG. 1. In FIG. 5, the open stub 105 is connected to the center of the transmission line 100 between the input terminal P10 and the output terminal P11 of the variable attenuator 10. The output results of the Smith chart at a plurality of positions of the variable attenuator 10 are shown in FIG. 6 to FIG. 10, respectively.

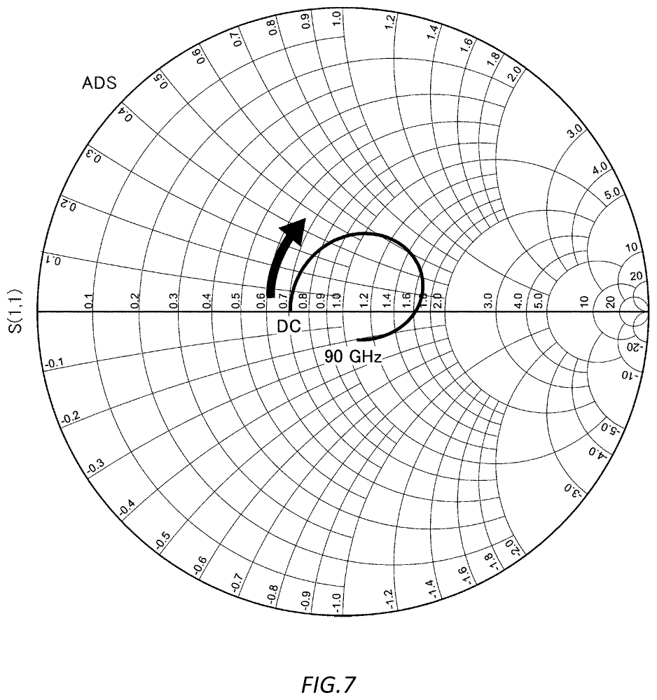

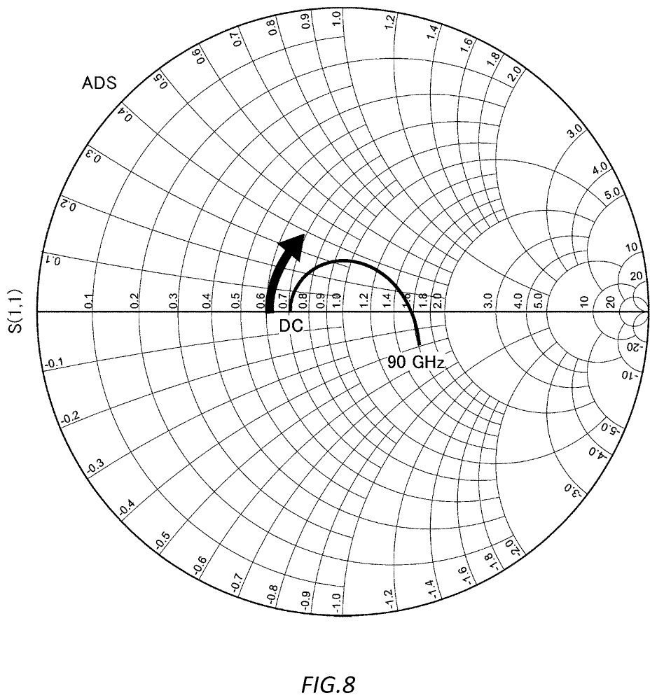

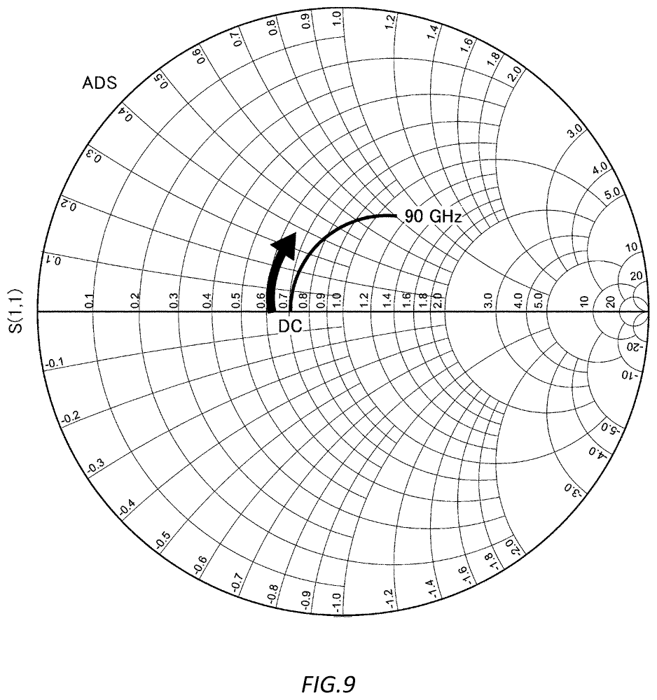

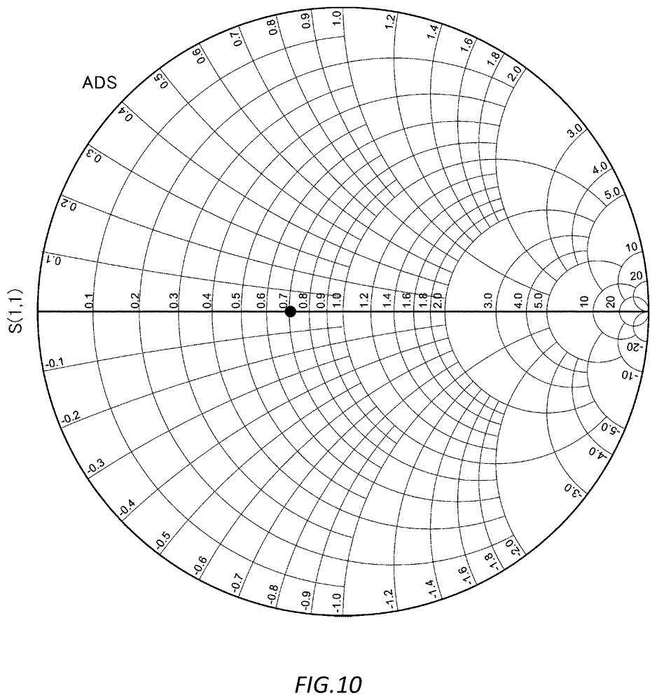

FIG. 6 shows an output result of the Smith chart at a position a of the variable attenuator 10 shown in FIG. 5. FIG. 7 shows an output result of the Smith chart at a position b of the variable attenuator 10 shown in FIG. 5. FIG. 8 shows an output result of the Smith chart at a position c of the variable attenuator 10 shown in FIG. 5. FIG. 9 shows an output result of the Smith chart at a position d of the variable attenuator 10 shown in FIG. 5. FIG. 10 shows an output result of the Smith chart at a position e of the variable attenuator 10 shown in FIG. 5. The Smith charts in FIG. 6 to FIG. 10 show, in bold lines, distributions of the impedance in a frequency range from 0 GHz (DC) to 90 GHz for the signal that is transmitted to the variable attenuator 10.

The open stub 105 behaves as a shunt capacitor in the variable attenuator 10, and thus by combining the open stub 105 with the transmission line 100 of λ/8 that is arranged between the position b and the position c, it is possible to compensate for a reactance component at a high frequency (here, near 90 GHz). On the Smith chart, in FIG. 6 to FIG. 8, the distribution near the high frequency is approaching the horizontal axis that represents the resistive component. As shown in FIG. 7 and FIG. 8, by utilizing the fact that the open stub 105 moves the impedance of the circuit counterclockwise on the Smith chart, the variable attenuator 10 of the present embodiment can shorten the electrical length Iₛₑᵣᵢₑₛ of the transmission line 100 between the input terminal P10 and the output terminal P11 to less than λ/4, and then convert the impedance to a target impedance. Accordingly, it is possible to shorten the electrical length of the transmission line 100 between the input terminal P10 and the output terminal P11 and to reduce a chip size.

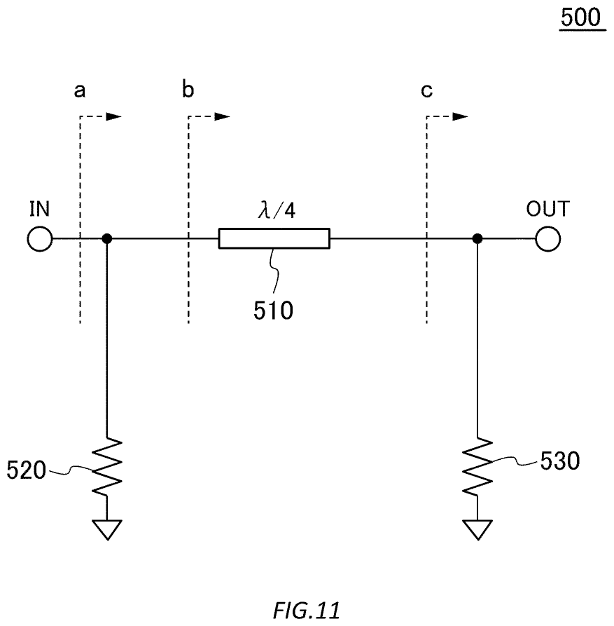

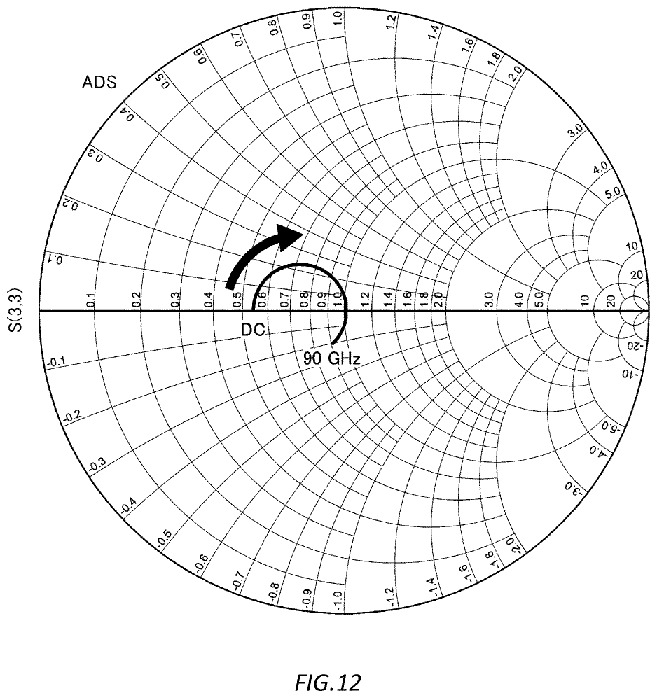

FIG. 11 is an illustration for describing an output result of the Smith chart at each position of a variable attenuator 500 in a Reference Example. The variable attenuator 500 of the Reference Example includes a transmission line 510, a fifth resistor 520, and a sixth resistor 530. The transmission line 510 has the same configuration as that of the transmission line 100 (in particular, the straight line of the transmission line 100) between the input terminal P10 and the output terminal P11 of the variable attenuator 10 shown in FIG. 5, but does not have the open stub. The fifth resistor 520 is connected between an input terminal IN and the reference potential, and has the same configuration as that of the first resistor 120 of the variable attenuator 10 in FIG. 5. The sixth resistor 530 is connected between an output terminal OUT and the reference potential, and has the same configuration as that of the second resistor 140 of the variable attenuator 10 in FIG. 5. The output results of the Smith chart at a plurality of positions of the variable attenuator 500 in the Reference Example are shown in FIG. 12 to FIG. 14, respectively.

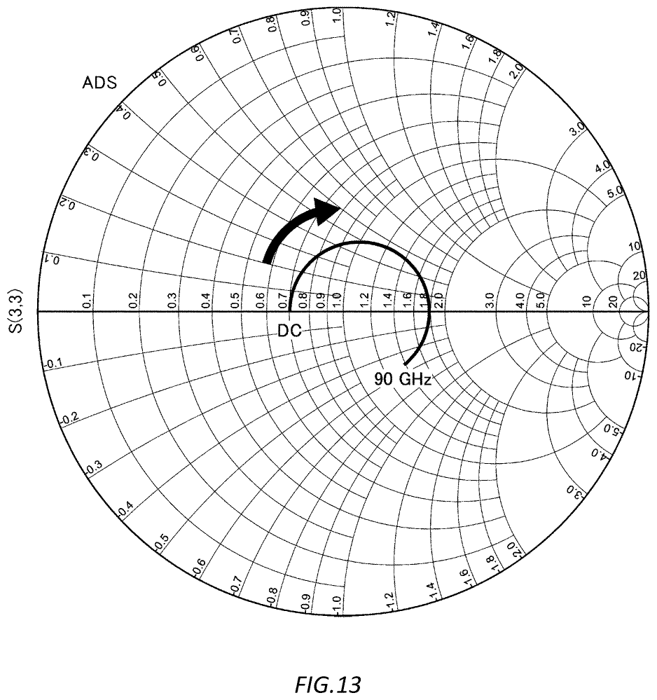

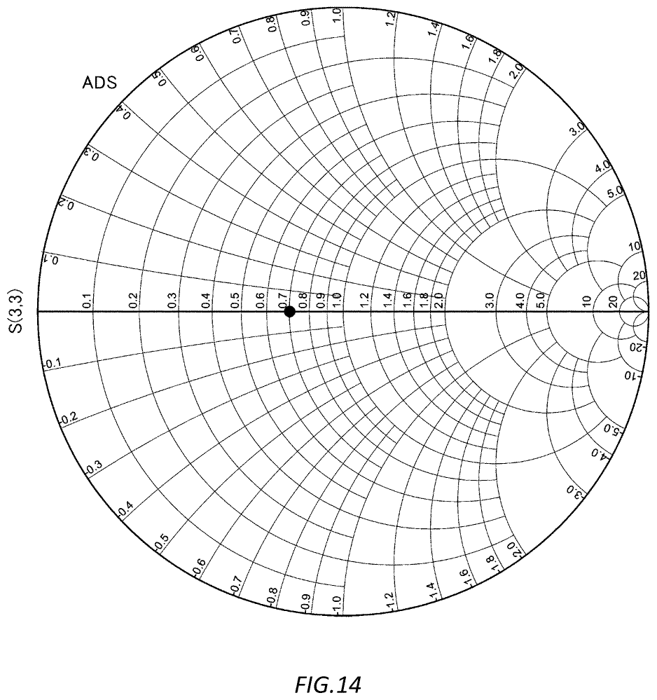

FIG. 12 shows an output result of the Smith chart at a position a of the variable attenuator 500 shown in FIG. 11. FIG. 13 shows an output result of the Smith chart at a position b of the variable attenuator 500 shown in FIG. 11. FIG. 14 shows an output result of the Smith chart at a position c of the variable attenuator 500 shown in FIG. 11. The Smith charts in FIG. 12 to FIG. 14 show, in bold lines, distributions of the impedance in a frequency range from 0 GHz (DC) to 90 GHz for the signal that is transmitted.

Between the position b and the position c, the impedance near the high frequency is distributed away from the horizontal axis, on the Smith chart shown in FIG. 12, by the transmission line 510. Accordingly, with the transmission line 510 alone, it is not possible to bring the impedance near the high frequency sufficiently close to the horizontal axis, and it is not possible to convert the impedance to the target impedance.

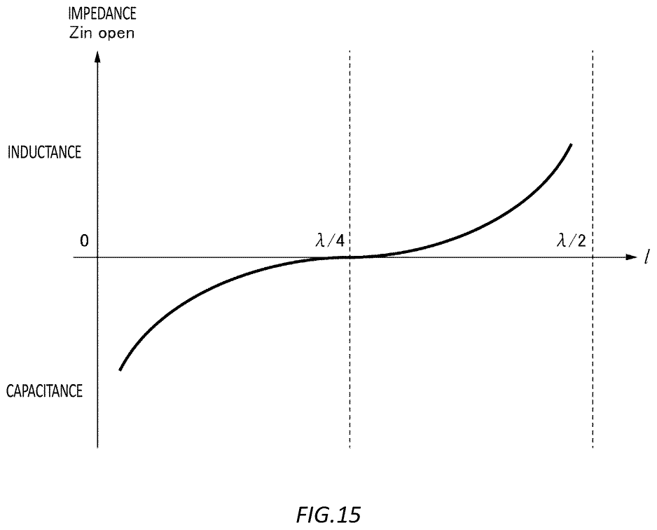

FIG. 15 shows a relationship between the impedance of the open stub 105 as seen from a connection position of the transmission line 100 and a length I_{stub}. In FIG. 15, the horizontal axis indicates the length I_{stub} of the open stub 105 from the connection position of the transmission line 100 between the input terminal P10 and the output terminal P11 in FIG. 1, and the vertical axis indicates the impedance of the open stub 105 as seen from the connection position of the transmission line 100. As shown in FIG. 15, in the range where the length of the open stub 105 satisfies 0<I_{stub}<λ/4 (in particular, λ/8≥I_{stub}), the open stub 105 exhibits the capacitance and operates as the shunt capacitor. Accordingly, in the variable attenuator 10 of the present embodiment, it is preferable for the electrical length of the open stub 105 to satisfy a range of 0<I_{stub}<λ/4, in particular, a range of λ/8≥I_{stub}.

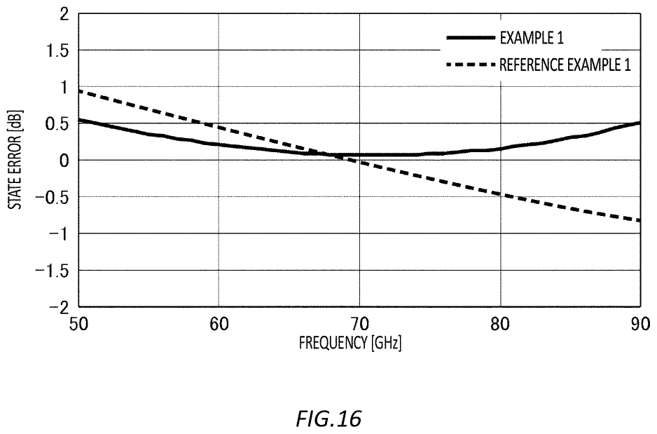

FIG. 16 shows a simulation result of a state error of the variable attenuator 10 having an attenuation amount of 8 dB. In FIG. 16, the horizontal axis indicates the frequency of the signal that is transmitted, and the vertical axis indicates the state error (a variation with respect to a nominal value of the attenuation amount). FIG. 16 shows, as Example 1, a simulation result of the state error of the variable attenuator 10 of the present embodiment in FIG. 2; and shows, as Reference Example 1, a simulation result of the state error of the variable attenuator which has the same configuration as that of the variable attenuator 10 of the present embodiment in FIG. 2, but does not have the open stub.

The state error in Example 1 is a maximum of 0.5 dB, and the state error in the Reference Example 1 is a maximum of 0.9 dB. It can be seen that the variable attenuator 10 of the present embodiment is used, thereby achieving an improvement in state error by 0.4 dB in comparison with Reference Example 1.

In comparison with the variable attenuator having an attenuation amount of 4 dB, the variable attenuator having an attenuation amount of 8 dB has a larger attenuation amount, and thus is required, in Reference Example 1, to increase a gate width of the shunt HEMT used as the switch, from a viewpoint of an allowable current and a distortion characteristic. Note that when the gate width of the shunt HEMT is increased, the capacitance of the circuit is increased, and it is not possible to perform the proper impedance conversion (impedance matching) for the large capacitance, which increases the state error of the variable attenuator. For example, for the variable attenuator which does not have the open stub, when the state errors of the configuration having the attenuation amount of 4 dB and the configuration having the attenuation amount of 8 dB are simulated, the state error of the variable attenuator having the attenuation amount of 4 dB (designed with a gate width of 25 μm) was a maximum of 0.4 dB, whereas the state error of the variable attenuator having the attenuation amount of 8 dB (designed with the gate width of 50 μm) was a maximum of 0.9 dB. As described above, there is a trade-off between the attenuation amount and the state error in the variable attenuator; however, in the variable attenuator 10 of the present embodiment, it is possible to use the open stub 105 to perform the impedance conversion, and reduce the state error even with a large attenuation amount.

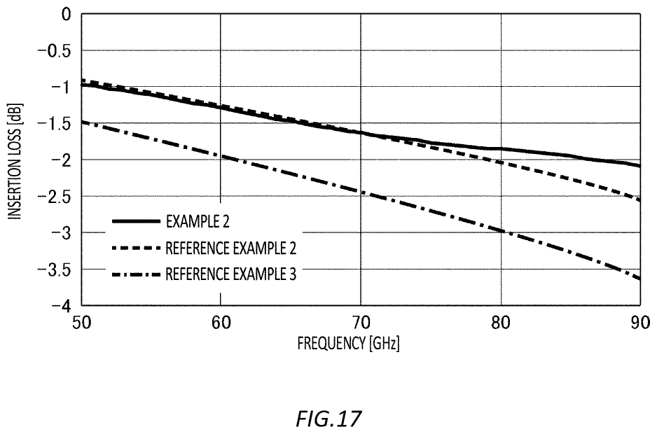

FIG. 17 shows simulation results of insertion losses of the step attenuator in Example 2, Reference Example 2, and Reference Example 3 when in Thru (when the attenuation amount is 0 dB). In FIG. 17, the horizontal axis indicates the frequency of the signal that is transmitted, and the vertical axis indicates the insertion loss (dB). The step attenuator 300 in Example 2 is configured by connecting in cascade five variable attenuators 10 of the present embodiment shown in FIG. 2. The step attenuator 300 in Example 2 operates at a frequency of 50 to 90 GHz; includes one variable attenuator 10 having an attenuation amount of 4 dB and three variable attenuators 10 having an attenuation amount of 8 dB; and has a total attenuation amount of 28 dB. Each of the five variable attenuators 10 has the electrical length of λ/4 between the input terminal P10 and the output terminal P11, and the first switch 110 and the second switch 130 are HEMTs.

Reference Example 2 uses the step attenuator having the same configuration as that of the step attenuator 300 in Example 2, but each of the variable attenuators of the step attenuator in Reference Example 2 does not have the open stub. The step attenuator in Reference Example 3 is configured by connecting in cascade the seven variable attenuators 10 of the present embodiment as shown in FIG. 2, but each variable attenuator of the step attenuator in Reference Example 2 does not have the open stub. The step attenuator in Reference Example 3 operates at a frequency of 50 to 90 GHz; includes seven variable attenuators having an attenuation amount of 4 dB; and has a total attenuation amount of 28 dB. Each switch in the variable attenuators in Reference Example 2 and Reference Example 3 is the HEMT.

In Reference Example 3, the gate width of the shunt HEMT used in each variable attenuator becomes small, and thus a capacitive effect caused by the switch becomes small; however, in order to achieve a desired total attenuation amount of 28 dB, the number of variable attenuators in the cascade connection becomes larger than in Reference Example 2. In a case where the insertion loss of each variable attenuator in Reference Example 3 when in Thru (when the attenuation amount is 0 dB) is a little more than 0.5 dB, by connecting seven variable attenuators in cascade, a total insertion loss of the step attenuator becomes a little more than 3.5 dB. In Example 2, the insertion loss when in Thru (when the attenuation amount is 0 dB) is 1.4 dB, showing a significant improvement, in comparison with Reference Example 3 in which the number of cascade connections is large.

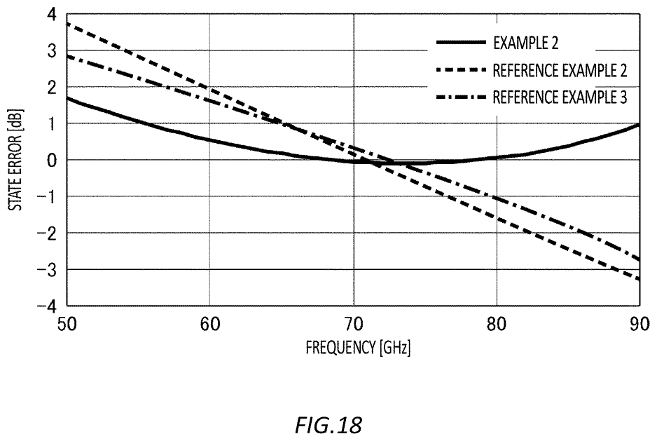

FIG. 18 shows simulation results of state errors of the step attenuator in Example 2, Reference Example 2, and Reference Example 3. In FIG. 18, the horizontal axis indicates the frequency of the signal that is transmitted, and the vertical axis indicates the state error (dB). Example 2, Reference Example 2, and Reference Example 3 in FIG. 18 are the step attenuators having the same configuration as in the simulation in FIG. 17.

In Reference Example 2, the variable attenuator having an attenuation amount of 8 dB is used, and thus the state error becomes larger than in Reference Example 3, and the state error as shown in FIG. 16 becomes larger by the cascade connection. In Example 2, an improvement in state error is achieved in comparison with Reference Example 2 and Reference Example 3.

In addition, in Reference Example 2, the length of the transmission line between the input terminal and the output terminal of the variable attenuator was 300 μm for the variable attenuator having an attenuation amount of 4 dB and 320 μm for the variable attenuator having an attenuation amount of 8 dB, whereas in Example 2, was 255 μm for the variable attenuator 10 with an attenuation amount of 4 dB, and was 270 μm for the variable attenuator 10 with an attenuation amount of 8 dB. Therefore, by using the step attenuator in Example 2, the chip size becomes approximately 15% smaller than the step attenuator in Reference Example 2. It should be noted that the open stub 105 in Example 2 is sufficiently shorter in length than the shunt HEMT or the resistor, and thus does not contribute to an increase in chip size.

With the variable attenuator 10 of the present embodiment as described above, it is possible to adjust the impedance by the transmission line 100 having the open stub 105, and thus it is possible to reduce the insertion loss when in Thru (when the attenuation amount is 0 dB), and further, it is possible to reduce the state error. In addition, with the variable attenuator 10 of the present embodiment, it becomes possible to shorten in design the transmission line 100 between the input terminal P10 and the output terminal P11, thereby reducing the chip size to contribute to a high-density implementation of the RF test front end.

While the embodiments of the present invention have been described, the technical scope of the present invention is not limited to the above-described embodiments. It is apparent to persons skilled in the art that various alterations or improvements can be added to the above-described embodiments. It is also apparent from the described scope of the claims that the embodiments to which such alterations or improvements are added can be included in the technical scope of the present invention.

Note that the operations, procedures, steps, stages, or the like of each process performed by a device, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

10 variable attenuator
100 transmission line
105 open stub
110 first switch
120 first resistor
130 second switch
140 second resistor
200 third switch
210 fourth switch
300 step attenuator
310 variable attenuator
320 variable attenuator
330 variable attenuator
340 variable attenuator
350 variable attenuator
360 variable attenuator
370 variable attenuator
400 test apparatus
410 test signal generation circuit
420 comparison circuit
430 connection device
442 first mixer
444 gain amplifier
446 first variable attenuator
448 first power amplifier
450 connection unit
460 second variable attenuator
462 second mixer
464 second power amplifier
470 DUT
500 variable attenuator
510 transmission line
520 fifth resistor
530 sixth resistor

What is claimed is:

1. A variable attenuator comprising:
a transmission line which has an open stub that is connected between an input and an output of the variable attenuator;
a first switch which is connected between the input and a reference potential; and
a second switch which is connected between the output and the reference potential.

2. The variable attenuator according to claim 1, comprising:
a first resistor which is connected in series with the first switch between the input and the reference potential; and
a second resistor which is connected in series with the second switch between the output and the reference potential.

3. The variable attenuator according to claim 2, wherein
the first resistor is connected to an end portion of the first switch on a reference potential side, and
the second resistor is connected to an end portion of the second switch on the reference potential side.

4. The variable attenuator according to claim 1, wherein
the open stub is connected at a center position in the transmission line between the input and the output of the variable attenuator.

5. The variable attenuator according to claim 2, wherein
the open stub is connected at a center position in the transmission line between the input and the output of the variable attenuator.

6. The variable attenuator according to claim 3, wherein
the open stub is connected at a center position in the transmission line between the input and the output of the variable attenuator.

7. The variable attenuator according to claim 1, wherein
the open stub has a length that is less than a length of the transmission line between the input and the output of the variable attenuator.

8. The variable attenuator according to claim 2, wherein
the open stub has a length that is less than a length of the transmission line between the input and the output of the variable attenuator.

9. The variable attenuator according to claim 3, wherein
the open stub has a length that is less than a length of the transmission line between the input and the output of the variable attenuator.

10. The variable attenuator according to claim 4, wherein
the open stub has a length that is less than a length of the transmission line between the input and the output of the variable attenuator.

11. A step attenuator comprising:
a plurality of variable attenuators, each of which is the variable attenuator according to claim 1, and which are connected in cascade.

12. A test apparatus comprising:
a test signal generation circuit which generates a test signal for testing a device under test;
a comparison circuit which compares, with an expected value, a response signal that is output by the device under test in response to the test signal; and
the variable attenuator according to claim 1 which attenuates the test signal or the response signal.

13. The test apparatus according to claim 12, comprising:
a gain amplifier which is connected between the test signal generation circuit and the variable attenuator, and amplifies the test signal.

14. The test apparatus according to claim 12, comprising:
a mixer which is connected between the comparison circuit and the variable attenuator, and converts a frequency of the response signal.

15. The test apparatus according to claim 13, comprising:
a mixer which is connected between the comparison circuit and the variable attenuator, and converts a frequency of the response signal.
